(19) United States
(12) Patent Application Publication
(10) Pub. No.: US 2026/0020318 A1
(43) Pub. Date: Jan. 15, 2026

(54) SEMICONDUCTOR DEVICE

(71) Applicant: SAMSUNG ELECTRONICS CO., LTD., Suwon-si (KR)

(72) Inventors: Jongyong Son, Suwon-si (KR); Suehye Park, Suwon-si (KR); Juyoun Kim, Suwon-si (KR); Hyung Jong Lee, Suwon-si (KR)

(73) Assignee: SAMSUNG ELECTRONICS CO., LTD., Suwon-si (KR)

(21) Appl. No.: 18/987,686

(22) Filed: Dec. 19, 2024

(30) Foreign Application Priority Data
Jul. 10, 2024 (KR) 10-2024-0091283

(51) Int. Cl. H10D 64/27; H10D 30/00

(52) U.S. Cl. CPC H10D 64/517; H10D 30/501

(57) ABSTRACT

A semiconductor device includes a substrate including an active pattern, a channel pattern on the active pattern, the channel pattern comprising semiconductor patterns, which are vertically stacked and are spaced apart from each other in a vertical direction, a source/drain pattern connected to the channel pattern, an inner gate electrode interposed between adjacent ones of the semiconductor patterns, an outer gate electrode on an uppermost one of the semiconductor patterns, a gate spacer on a side surface of the outer gate electrode, and a gate capping pattern on a top surface of the outer gate electrode. The gate capping pattern is in contact with a top surface of the gate spacer.

### CROSS-REFERENCE TO RELATED APPLICATIONS

This U.S. non-provisional patent application claims priority under 35 U.S.C. § 119 to Korean Patent Application No. 10-2024-0091283, filed on Jul. 10, 2024, in the Korean Intellectual Property Office, the entire contents of which being hereby incorporated by reference.

### BACKGROUND

The present disclosure relates to semiconductor devices and methods of fabricating the same, and in particular, to semiconductor devices including field effect transistors and methods of fabricating the same.

A semiconductor device includes an integrated circuit composed of metal-oxide-semiconductor field-effect transistors (MOS-FETs). To meet an increasing demand for a semiconductor device with a small pattern size and a reduced design rule, the MOS-FETs are being aggressively scaled down. The scale-down of the MOS-FETs may lead to deterioration in operational properties of the semiconductor device. A variety of studies are being conducted to overcome technical limitations associated with the scale-down of the semiconductor device and to realize high-performance semiconductor devices.

### SUMMARY

It is an aspect to provide a semiconductor device with improved electrical and reliability characteristics.

According to an aspect of one or more embodiments, there is provided a semiconductor device comprising a substrate including an active pattern; a channel pattern on the active pattern, the channel pattern comprising a plurality of semiconductor patterns, which are vertically stacked and are spaced apart from each other in a vertical direction; a source/drain pattern connected to the channel pattern; an inner gate electrode interposed between adjacent ones of the plurality of semiconductor patterns; an outer gate electrode on an uppermost one of the plurality of semiconductor patterns; a gate spacer on a side surface of the outer gate electrode; and a gate capping pattern on a top surface of the outer gate electrode. The gate capping pattern is in contact with a top surface of the gate spacer.

According to another aspect of one or more embodiments, there is provided a semiconductor device comprising a substrate including an active pattern; a channel pattern on the active pattern, the channel pattern comprising a plurality of semiconductor patterns, which are vertically stacked and are spaced apart from each other in a vertical direction; a source/drain pattern connected to the channel pattern; an inner gate electrode interposed between adjacent ones of the plurality of semiconductor patterns; an outer gate electrode on an uppermost one of the plurality of semiconductor patterns; a silicon nitride layer on side surfaces and a top surface of the outer gate electrode; a silicon oxide layer covering the source/drain pattern; and an active contact that penetrates the silicon oxide layer and is connected to the source/drain pattern. A side surface of the active contact is in contact with the silicon oxide layer and is spaced apart from the silicon nitride layer.

According to yet another aspect of one or more embodiments, there is provided a semiconductor device comprising a substrate including an active pattern; a channel pattern on the active pattern, the channel pattern comprising a plurality of semiconductor patterns, which are vertically stacked and are spaced apart from each other in a vertical direction; a source/drain pattern connected to the channel pattern; an inner gate electrode interposed between adjacent ones of the plurality of semiconductor patterns; an outer gate electrode on an uppermost one of the plurality of semiconductor patterns; a gate spacer on a side surface of the outer gate electrode; a gate capping pattern on a top surface of the outer gate electrode; a first interlayer insulating layer covering the source/drain pattern; a second interlayer insulating layer on the first interlayer insulating layer; and an active contact that penetrates the first interlayer insulating layer, the second interlayer insulating layer, and an upper portion of the source/drain pattern. The gate capping pattern is spaced apart from the active contact in a first direction. The active contact comprises a first portion that penetrates the first interlayer insulating layer and the second interlayer insulating layer; and a second portion that penetrates the upper portion of the source/drain pattern. The first portion has a first width in the first direction, and a distance between the gate capping pattern and the active contact in the first direction is equal to or greater than half the first width.

### BRIEF DESCRIPTION OF THE DRAWINGS

FIGS. 1, 2, and 3 are conceptual diagrams illustrating logic cells of a semiconductor device according to some embodiments.

FIG. 4 is a plan view illustrating a semiconductor device according to some embodiments.

FIG. 5A is a sectional view taken along a line A-A′ of FIG. 4.

FIG. 5B is a sectional view taken along a line B-B′ of FIG. 4.

FIG. 5C is a sectional view taken along a line C-C′ of FIG. 4.

FIG. 5D is a sectional view taken along a line D-D′ of FIG. 4.

FIG. 6 is an enlarged view illustrating a portion ‘CU’ of FIG. 5A.

FIGS. 7A, 7B, 8A, 8B, 9A, 9B, 9C, 9D, 10A, 10B, 10C, 10D, 11A, 11B, 11C, 11D, 12A, 12B, 12C, 12D, 13A, 13B, 13C, 13D, 14A, 14B, 14C, 14D, 15A, 15B, 15C, 15D, 16A, 16B, 16C, and 16D are sectional views illustrating a method of fabricating a semiconductor device, according to some embodiments.

### DETAILED DESCRIPTION

Example embodiments will now be described more fully with reference to the accompanying drawings, in which example embodiments are shown. As used in this specification, a phrase using the form “at least one of A, B, or C” includes within its scope “only A”, “only B”, “only C”, “A and B”, “A and C”, “B and C” and “A, B, and C.”

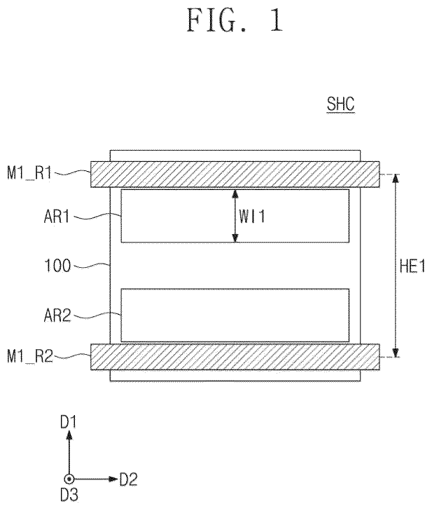

FIGS. 1, 2, and 3 are conceptual diagrams illustrating logic cells of a semiconductor device according to some embodiments.

Referring to FIG. 1, a single height cell SHC may be provided. In detail, a first power line M1_R1 and a second power line M1_R2 may be provided on a substrate 100. The first power line M1_R1 may be a conduction path, to which a source voltage VSS (e.g., a ground voltage) is provided. The second power line M1_R2 may be a conduction path, to which a drain voltage VDD (e.g., a power voltage) is provided.

The single height cell SHC may be defined between the first power line M1_R1 and the second power line M1_R2. In some embodiments, the single height cell SHC may include a first active region AR1 and a second active region AR2. In some embodiments, the single height cell SHC may include one first active region AR1 and one second active region AR2. One of the first and second active regions AR1 and AR2 may be a PMOSFET region, and the other may be an NMOSFET region. That is, the single height cell SHC may have a CMOS structure provided between the first power line M1_R1 and the second power line M1_R2. For example, the first active region AR1 may be an NMOSFET region, and the second active region AR2 may be a PMOSFET region.

In the present specification, a first direction D1 may be defined as a direction parallel to a top surface of the substrate 100. A second direction D2 may be defined as a direction that is parallel to the top surface of the substrate 100 and is perpendicular to the first direction D1. A third direction D3 may be defined as a direction that is perpendicular to the top surface of the substrate 100. The third direction D3 may also be referred to as a vertical direction in some instances.

In some embodiments, each of the first and second active regions AR1 and AR2 may have a single width W11 in the first direction D1. It is noted that FIG. 1 illustrates the width W11 for the first active region AR1. However, it will be understood that, in some embodiments, the second active region AR2 may have the first width W11. A length of the single height cell SHC in the first direction D1 may be defined as a first height HE1. The first height HE1 may be substantially equal to a length (e.g., a pitch) between the first power line M1_R1 and the second power line M1_R2.

The single height cell SHC may constitute a single logic cell. In the present specification, the logic cell may mean a logic device (e.g., AND, OR, XOR, XNOR, inverter, and so forth), which is configured to execute a specific function. In other words, the logic cell may include transistors constituting the logic device and interconnection lines connecting the transistors to each other.

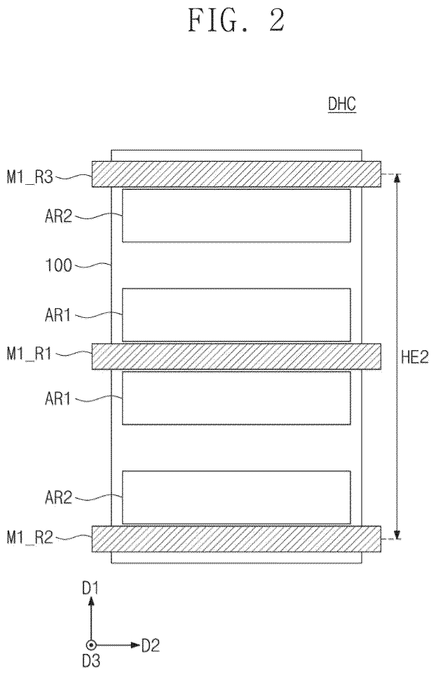

Referring to FIG. 2, a double height cell DHC may be provided. In detail, the first power line M1_R1, the second power line M1_R2, and a third power line M1_R3 may be provided on the substrate 100. The first power line M1_R1 may be disposed between the second power line M1_R2 and the third power line M1_R3. The third power line M1_R3 may be a conduction path, to which the source voltage VSS is provided.

The double height cell DHC may be defined between the second power line M1_R2 and the third power line M1_R3. The double height cell DHC may include a pair of first active regions AR1 and a pair of second active regions AR2. For example, in some embodiments, the double height cell DHC may include two first active regions AR1 and two second active regions AR2

One of the pair of second active regions AR2 may be adjacent to the second power line M1_R2. The other of the pair of second active regions AR2 may be adjacent to the third power line M1_R3. The pair of first active regions AR1 may be adjacent to the first power line M1_R1. When viewed in a plan view, the first power line M1_R1 may be disposed between the pair of first active regions AR1.

A length of the double height cell DHC in the first direction D1 may be defined as a second height HE2. The second height HE2 may be about two times the first height HE1 of the single height cell SHC illustrated in FIG. 1. In some embodiments, the pair of the first active regions AR1 of the double height cell DHC may be combined to serve as a single active region.

In an embodiment, the double height cell DHC shown in FIG. 2 may be defined as a multi-height cell. Although not shown, the multi-height cell may include a triple height cell whose cell height is about three times the height HE1 of the single height cell SHC.

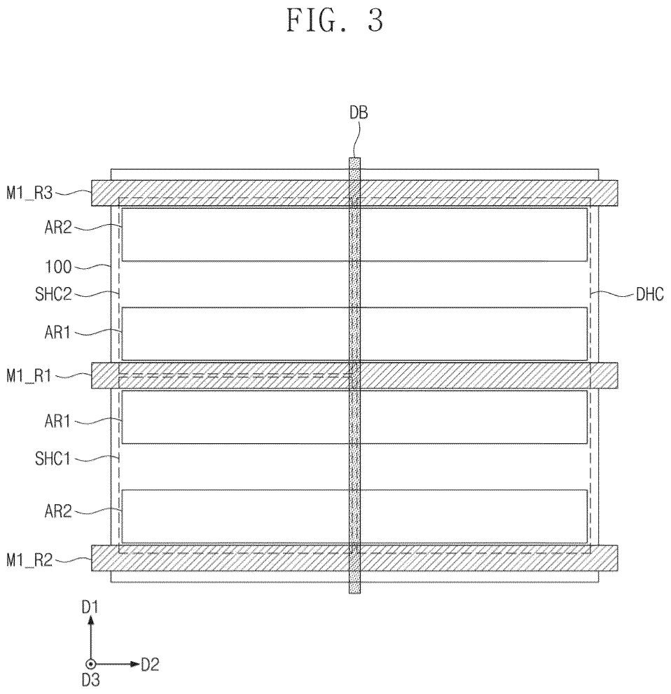

Referring to FIG. 3, a first single height cell SHC1, a second single height cell SHC2, and a double height cell DHC may be two-dimensionally arranged on the substrate 100. The first single height cell SHC1 may be disposed between the first and second power lines M1_R1 and M1_R2. The second single height cell SHC2 may be disposed between the first and third power lines M1_R1 and M1_R3. The second single height cell SHC2 may be adjacent to the first single height cell SHC1 in the first direction D1.

The double height cell DHC may be disposed between the second and third power lines M1_R2 and M1_R3. The double height cell DHC may be adjacent to the first and second single height cells SHC1 and SHC2 in the second direction D2.

A division structure DB may be provided between the first single height cell SHC1 and the double height cell DHC and between the second single height cell SHC2 and the double height cell DHC. The active region of the double height cell DHC may be electrically separated from the active region of each of the first and second single height cells SHC1 and SHC2 by the division structure DB.

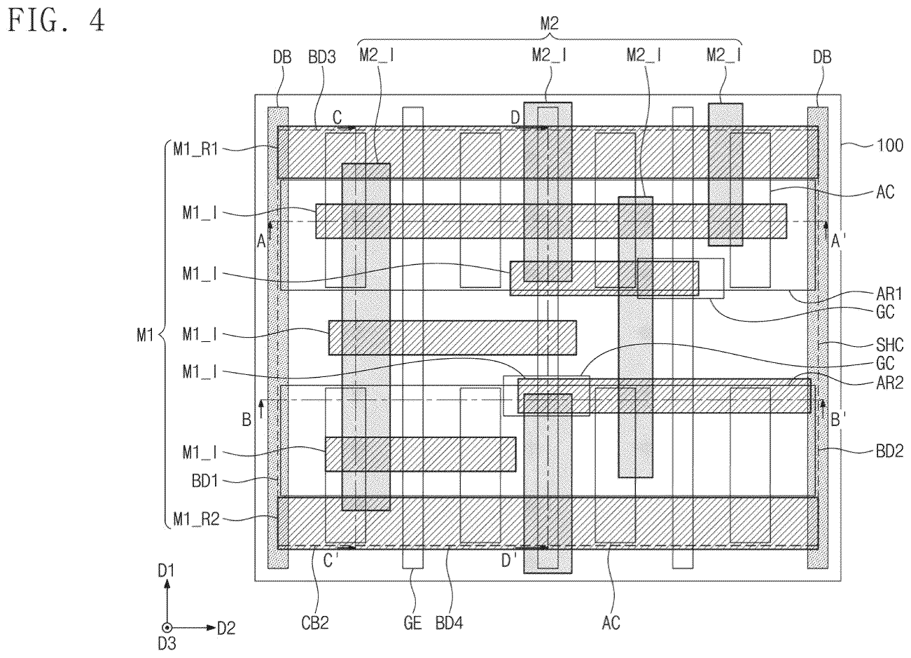

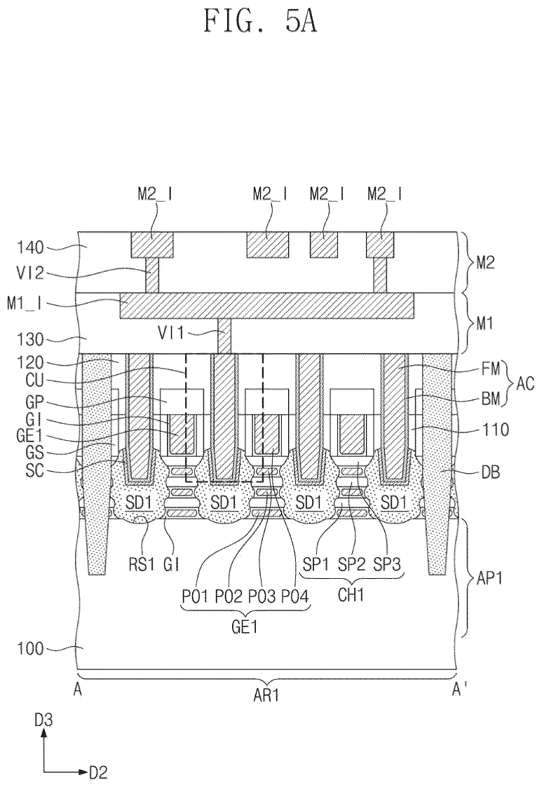

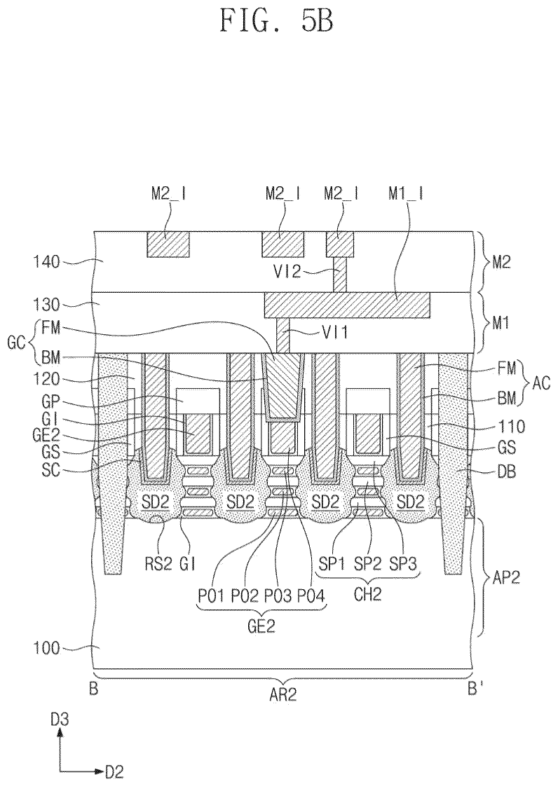

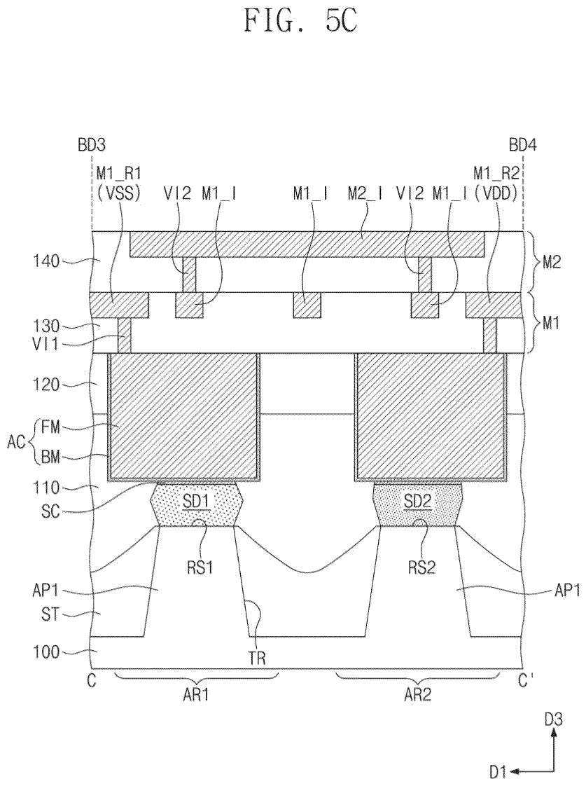

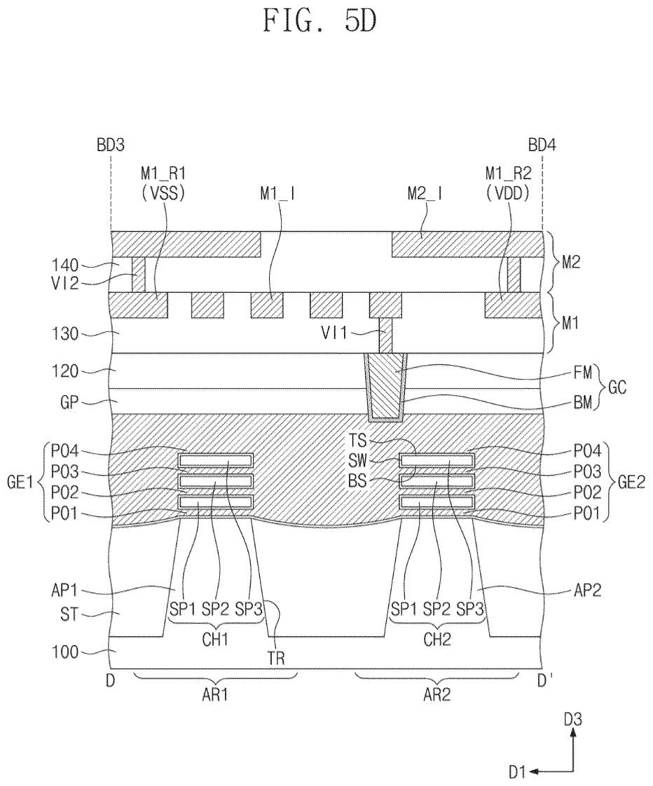

FIG. 4 is a plan view illustrating a semiconductor device according to some embodiments. FIG. 5A is a sectional view taken along a line A-A′ of FIG. 4. FIG. 5B is a sectional view taken along a line B-B′ of FIG. 4. FIG. 5C is a sectional view taken along a line C-C′ of FIG. 4. FIG. 5D is a sectional view taken along a line D-D′ of FIG. 4. The semiconductor device of FIGS. 4 and 5A to 5D may be a concrete example of the single height cell SHC of FIG. 1.

Referring to FIGS. 4 and 5A to 5D, the single height cell SHC may be provided on the substrate 100. Logic transistors constituting a logic circuit may be disposed on the single height cell SHC. The substrate 100 may be a semiconductor substrate that is formed of or includes silicon, germanium, silicon germanium, a compound semiconductor material, or the like. In an embodiment, the substrate 100 may be a silicon wafer.

The substrate 100 may include the first active region AR1 and the second active region AR2. Each of the first and second active regions AR1 and AR2 may extend in the second direction D2. In an embodiment, the first active region AR1 may be an NMOSFET region, and the second active region AR2 may be a PMOSFET region.

A first active pattern AP1 and a second active pattern AP2 may be defined by a trench TR, which is formed in an upper portion of the substrate 100. The first active pattern AP1 may be provided on the first active region AR1, and the second active pattern AP2 may be provided on the second active region AR2. The first and second active patterns AP1 and AP2 may extend in the second direction D2. Each of the first and second active patterns AP1 and AP2 may be a vertically-protruding portion of the substrate 100.

A device isolation layer ST may be provided on the substrate 100. The device isolation layer ST may fill the trench TR. The device isolation layer ST may be formed of or include silicon oxide. In some embodiments, the device isolation layer ST may not cover first and second channel patterns CH1 and CH2 to be described below.

A first channel pattern CH1 may be provided on the first active pattern AP1. A second channel pattern CH2 may be provided on the second active pattern AP2. Each of the first and second channel patterns CH1 and CH2 may include a plurality of semiconductor patterns, which are sequentially stacked in a vertical direction (e.g., the third direction D3). For example, the plurality of semiconductor patterns may include a first semiconductor pattern SP1, a second semiconductor pattern SP2, and a third semiconductor pattern SP3, which are sequentially stacked in the vertical direction. The first to third semiconductor patterns SP1, SP2, and SP3 may be spaced apart from each other in the vertical direction (i.e., the third direction D3).

Each of the first to third semiconductor patterns SP1, SP2, and SP3 may be formed of or include at least one of silicon (Si), germanium (Ge), or silicon germanium (SiGe). For example, each of the first to third semiconductor patterns SP1, SP2, and SP3 may be formed of or include crystalline silicon. In an embodiment, the first to third semiconductor patterns SP1, SP2, and SP3 may be nanosheets that are stacked.

A plurality of first source/drain patterns SD1 may be provided on the first active pattern AP1. A plurality of first recesses RS1 may be formed in an upper portion of the first active pattern AP1. The first source/drain patterns SD1 may be provided in the first recesses RS1, respectively. The first source/drain patterns SD1 may be impurity regions of a first conductivity type (e.g., n-type). In an embodiment, the first channel pattern CH1 may be interposed between each pair of the first source/drain patterns SD1. For example, in some embodiments, the first channel pattern CH1 may be interposed between each adjacent two of the first source/drain patterns SD. In other words, each adjacent two of the first source/drain patterns SD1 may be connected to each other by the stacked first to third semiconductor patterns SP1, SP2, and SP3.

A plurality of second source/drain patterns SD2 may be provided on the second active pattern AP2. A plurality of second recesses RS2 may be formed in an upper portion of the second active pattern AP2. The second source/drain patterns SD2 may be provided in the second recesses RS2, respectively. The second source/drain patterns SD2 may be impurity regions of a second conductivity type (e.g., p-type). In an embodiment, the second channel pattern CH2 may be interposed between each pair of the second source/drain patterns SD2. For example, in some embodiments, the second channel pattern CH2 may be interposed between each adjacent two of the second source/drain patterns SD2. In other words, each adjacent two of the second source/drain patterns SD2 may be connected to each other by the stacked first to third semiconductor patterns SP1, SP2, and SP3.

The first and second source/drain patterns SD1 and SD2 may be epitaxial patterns, which are formed by a selective epitaxial growth (SEG) process. In an embodiment, a top surface of each of the first and second source/drain patterns SD1 and SD2 may be vertically higher than a top surface of the third semiconductor pattern SP3. In some embodiments, at least one of the first and second source/drain patterns SD1 and SD2 may have a top surface that is located at substantially the same vertical level as the top surface of the third semiconductor pattern SP3.

In an embodiment, the first source/drain patterns SD1 may be formed of or include the same semiconductor element (e.g., Si) as the substrate 100. The second source/drain patterns SD2 may include a semiconductor material (e.g., SiGe) whose lattice constant is greater than a lattice constant of the substrate 100. In this case, the pair of the second source/drain patterns SD2 may exert a compressive stress on the second channel pattern CH2 therebetween.

In an embodiment, a side surface of each of the first and second source/drain patterns SD1 and SD2 may have an uneven or embossing shape. In other words, the side surface of each of the first and second source/drain patterns SD1 and SD2 may have a wavy profile. A side surface of each of the first and second source/drain patterns SD1 and SD2 may protrude toward first to third inner gate electrodes PO1, PO2, and PO3 of first and second gate electrodes GE1 and GE2 to be described below.

A first gate electrode GE1 and a second gate electrode GE2 may be provided on the first and second channel patterns CH1 and CH2, respectively. The first and second gate electrodes GE1 and GE2 may extend in the first direction D1 to cross the first and second channel patterns CH1 and CH2. The gate electrodes GEL and GE2 may be vertically overlapped with the first and second channel patterns CH1 and CH2, respectively. The first and second gate electrodes GE1 and GE2 may be arranged at a first pitch in the second direction D2.

Each of the first and second gate electrodes GE1 and GE2 may include a first inner gate electrode PO1 interposed between the active pattern AP1 or AP2 and the first semiconductor pattern SP1, a second inner gate electrode PO2 interposed between the first semiconductor pattern SP1 and the second semiconductor pattern SP2, a third inner gate electrode PO3 interposed between the second semiconductor pattern SP2 and the third semiconductor pattern SP3, and an outer gate electrode PO4 on the third semiconductor pattern SP3. That is, the outer gate electrode PO4 may be provided on the uppermost one (e.g., SP3) of the semiconductor patterns SP1, SP2, and SP3.

Referring to FIG. 5D, the first and second gate electrodes GE1 and GE2 may be provided on a top surface TS, a bottom surface BS, and opposite side surfaces SW of each of the first to third semiconductor patterns SP1, SP2, and SP3. A transistor according to an embodiment may be a three-dimensional field effect transistor (e.g., MBCFET or GAAFET) in which the first and second gate electrodes GE1 and GE2 are provided to three-dimensionally surround the channel pattern.

A gate electrode GE (i.e., each of the first and second gate electrodes GE1 and GE2) may include a first metal pattern and a second metal pattern on the first metal pattern. The first metal pattern may be adjacent to the first to third semiconductor patterns SP1, SP2, and SP3. The first metal pattern may include a work-function metal, which can be used to adjust a threshold voltage of the transistor. By adjusting a thickness and composition of the first metal pattern, it may be possible to realize a transistor having a desired threshold voltage. For example, the first to third inner electrodes PO1, PO2, and PO3 of the gate electrode GE may be composed of the first metal pattern or the work-function metal.

The first metal pattern may include a metal nitride layer. For example, the first metal pattern may include a layer that is composed of at least one metallic material, which is selected from the group consisting of titanium (Ti), tantalum (Ta), aluminum (Al), tungsten (W) and molybdenum (Mo), and nitrogen (N). In an embodiment, the first metal pattern may further include carbon (C). The first metal pattern may include a plurality of work function metal layers which are stacked.

The second metal pattern may be formed of or include a metallic material whose resistance is lower than the first metal pattern. For example, the second metal pattern may be formed of or include at least one metallic material, which is selected from the group consisting of tungsten (W), aluminum (Al), titanium (Ti), and tantalum (Ta). For example, the outer gate electrode PO4 of the gate electrode GE may include the first metal pattern and the second metal pattern on the first metal pattern.

Referring back to FIGS. 5A to 5D, a pair of gate spacers GS may be respectively disposed on side surfaces of the outer gate electrodes PO4 of the first and second gate electrodes GE1 and GE2. For example, in some embodiments, a gate spacers GS may be disposed on each side surface of the outer gate electrodes PO4 of the first and second gate electrodes GE1 and GE2. The gate spacers GS may extend along the first and second gate electrodes GE1 and GE2 and in the first direction D1. The gate spacers GS may include at least one of silicon oxynitride (SiON), silicon nitride (SiN), or silicon carbon nitride (SiCN).

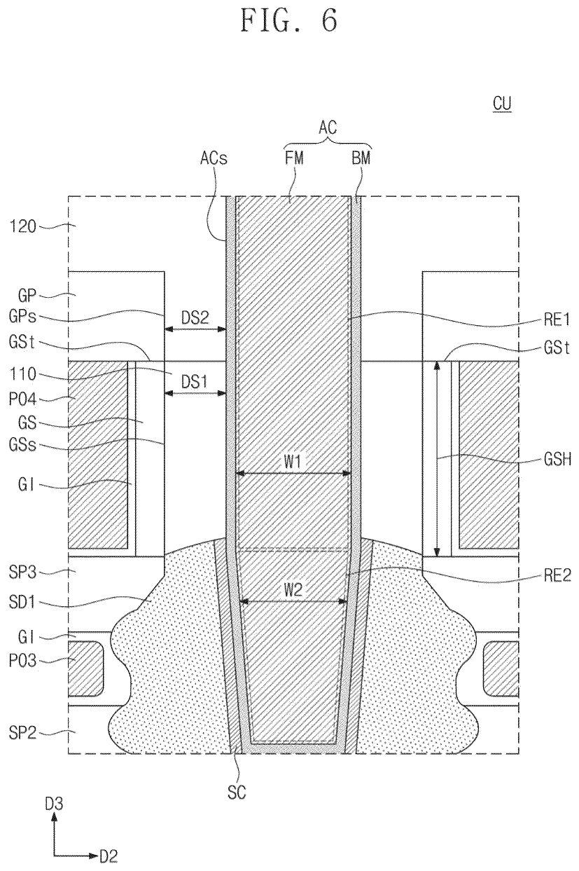

A gate capping pattern GP may be provided on a top surface of the outer gate electrode PO4 of each of the first and second gate electrodes GE1 and GE2. The gate capping pattern GP may extend along the first and second gate electrodes GE1 and GE2 and in the first direction D1. The gate capping pattern GP may be formed of or include a material having an etch selectivity with respect to first and second interlayer insulating layers 110 and 120, which will be described below. In an embodiment, the gate capping pattern GP may include at least one of silicon oxynitride (SiON), silicon nitride (SiN), or silicon carbon nitride (SiCN). In the present specification, the gate spacer GS and the gate capping pattern GP may be referred to as a silicon nitride layer, which is a single object. The gate spacers GS and the gate capping pattern GP will be described in more detail with reference to FIG. 6.

A gate insulating layer GI may be interposed between the first gate electrode GE1 and the first channel pattern CH1 and between the second gate electrode GE2 and the second channel pattern CH2. In some embodiments, the gate insulating layer GI may cover the top surface TS, the bottom surface BS, and the side surfaces SW of each of the first to third inner electrodes PO1, PO2, and PO3. The gate insulating layer GI may cover a top surface of the device isolation layer ST below the first and second gate electrodes GEL and GE2.

In an embodiment, the gate insulating layer GI may include a silicon oxide layer, a silicon oxynitride layer, and/or a high-k dielectric layer. The high-k dielectric layer may be formed of or include at least one of high-k dielectric materials whose dielectric constants are higher than that of silicon oxide. For example, the high-k dielectric material may include at least one of hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, or lead zinc niobate.

A first interlayer insulating layer 110 may be provided on the substrate 100. The first interlayer insulating layer 110 may cover the first and second source/drain patterns SD1 and SD2. A second interlayer insulating layer 120 may be provided on the first interlayer insulating layer 110. A third interlayer insulating layer 130 may be provided on the second interlayer insulating layer 120. A fourth interlayer insulating layer 140 may be provided on the third interlayer insulating layer 130. In an embodiment, the first to fourth interlayer insulating layers 110 to 140 may be formed of or include silicon oxide. In the present specification, the first to fourth interlayer insulating layers 110 to 140 may be referred to as a silicon oxide layer.

The single height cell SHC may have a first border BD1 and a second border BD2, which are opposite to each other in the second direction D2. The first and second borders BD1 and BD2 may extend in the first direction D1. The single height cell SHC may have a third border BD3 and a fourth border BD4, which are opposite to each other in the first direction D1. The third and fourth borders BD3 and BD4 may extend in the second direction D2.

A pair of division structures DB, which are opposite to each other in the second direction D2, may be provided at both sides of the single height cell SHC. For example, in some embodiments, two division structures DB, which are opposite to each other in the second direction D2, may be provided, one on each side of the single height cell SHC in the second direction D2. For example, the division structures DB may be respectively provided on the first and second borders BD1 and BD2 of the single height cell SHC. The division structure DB may extend in the first direction D1 to be parallel to the first and second gate electrodes GE1 and GE2.

The division structure DB may be provided to penetrate the first and second interlayer insulating layers 110 and 120 and may extend into the first and second active patterns AP1 and AP2. The division structure DB may be provided to penetrate an upper portion of each of the first and second active patterns AP1 and AP2. The division structure DB may electrically separate an active region of the single height cell SHC from an active region of a neighboring cell.

Active contacts AC may be provided to penetrate the first and second interlayer insulating layers 110 and 120 and to be electrically connected to the first and second source/drain patterns SD1 and SD2, respectively. The active contact AC may be provided to penetrate upper portions of the first and second source/drain patterns SD1 and SD2. The active contacts AC may be respectively provided at both sides of the gate electrode GE (e.g., the first gate electrode GE1 and the second gate electrode GE2). When viewed in a plan view, the active contact AC may be a bar-shaped pattern that is extended in the first direction D1.

Metal-semiconductor compound layers SC (e.g., silicide layers) may be respectively interposed between the active contact AC and the first source/drain pattern SD1 and between the active contact AC and the second source/drain pattern SD2. The active contact AC may be electrically connected to the source/drain pattern SD1 or SD2 through the metal-semiconductor compound layer SC. For example, the metal-semiconductor compound layer SC may be formed of or include at least one of titanium silicide, tantalum silicide, tungsten silicide, nickel silicide, or cobalt silicide.

Gate contacts GC may be provided to penetrate the second interlayer insulating layer 120 and the gate capping pattern GP and may be electrically connected to the gate electrodes GE, respectively. When viewed in a plan view, the gate contacts GC may be disposed to be overlapped with the first and second active regions AR1 and AR2, respectively. As an example, the gate contact GC may be provided on the second active pattern AP2 (e.g., see FIG. 5B).

Each of the active contacts AC and the gate contacts GC may include a conductive pattern FM and a barrier pattern BM enclosing the conductive pattern FM. For example, the conductive pattern FM may be formed of or include at least one of metallic materials (e.g., aluminum, copper, tungsten, molybdenum, and cobalt). The barrier pattern BM may be provided to cover side and bottom surfaces of the conductive pattern FM. In an embodiment, the barrier pattern BM may include a metal layer and a metal nitride layer. The metal layer may be formed of or include at least one of titanium, tantalum, tungsten, nickel, cobalt, or platinum. The metal nitride layer may be formed of or include at least one of titanium nitride (TiN), tantalum nitride (TaN), tungsten nitride (WN), nickel nitride (NiN), cobalt nitride (CON), or platinum nitride (PtN).

A first metal layer M1 may be provided in the third interlayer insulating layer 130. For example, the first metal layer M1 may include a first power line M1_R1, a second power line M1_R2, and first interconnection lines M1_I. The interconnection lines M1_R1, M1_R2, and M1_I of the first metal layer M1 may extend in the second direction D2 to be parallel to each other.

In detail, the first and second power lines M1_R1 and M1_R2 may be respectively provided on the third and fourth borders BD3 and BD4 of the single height cell SHC. The first power line M1_R1 may extend along the third border BD3 and in the second direction D2. The second power line M1_R2 may extend along the fourth border BD4 and in the second direction D2.

The first interconnection lines M1_I of the first metal layer M1 may be disposed between the first and second power lines M1_R1 and M1_R2. The first interconnection lines M1_I of the first metal layer M1 may be arranged at a second pitch in the first direction D1. The second pitch may be smaller than the first pitch. A linewidth of each of the first interconnection lines M1_I may be smaller than a linewidth of each of the first and second power lines M1_R1 and M1_R2.

The first metal layer M1 may further include first vias VI1. The first vias VI1 may be provided below the interconnection lines M1_R1, M1_R2, and M1_I, respectively, of the first metal layer M1. The active contact AC and the interconnection line of the first metal layer M1 may be electrically connected to each other through the first via VI1. The gate contact GC and the interconnection line of the first metal layer M1 may be electrically connected to each other through the first via VI1.

The interconnection line of the first metal layer M1 and the first via VI1 thereunder may be formed by separate processes. For example, the interconnection line and the first via VI1 of the first metal layer M1 may be independently formed by respective single damascene processes.

A second metal layer M2 may be provided in the fourth interlayer insulating layer 140. The second metal layer M2 may include a plurality of second interconnection lines M2_I. Each of the second interconnection lines M2_I of the second metal layer M2 may be a line- or bar-shaped pattern that is extended in the first direction D1. In other words, the second interconnection lines M2_I may extend in the first direction D1 to be parallel to each other.

The second metal layer M2 may further include second vias VI2, which are respectively provided below the second interconnection lines M2_I. The interconnection lines of the first and second metal layers M1 and M2 may be electrically connected to each other through the second via VI2. The interconnection line of the second metal layer M2 and the second via VI2 thereunder may be formed together by a dual damascene process.

The interconnection lines of the first metal layer M1 may be formed of or include a conductive material that is the same as or different from those of the second metal layer M2. For example, the interconnection lines of the first and second metal layers M1 and M2 may be formed of or include at least one of metallic materials (e.g., aluminum, copper, tungsten, ruthenium, molybdenum, and cobalt). Although not shown, in some embodiments, a plurality of metal layers (e.g., M3, M4, M5, and so forth) may be additionally stacked on the fourth interlayer insulating layer 140. Each of the stacked metal layers may include interconnection lines, which are used as routing paths between cells.

FIG. 6 is an enlarged view illustrating a portion ‘CU’ of FIG. 5A. Technical features to be described with reference to FIG. 6 may be applied to elements disposed on the second active region AR2 of FIG. 5B in substantially the same manner. An element previously described with reference to FIGS. 5A to 5D may be identified by the same reference number without repeating an overlapping description thereof for conciseness.

Referring to FIG. 6, the gate capping pattern GP may be in contact with a top surface GSt of the gate spacer GS. The gate capping pattern GP may be placed at a level higher than the first interlayer insulating layer 110 in the third direction D3 (i.e., the vertical direction). In detail, the gate capping pattern GP may be provided in the second interlayer insulating layer 120. In other words, the second interlayer insulating layer 120 may cover a side surface GPs and a top surface of the gate capping pattern GP. When viewed in a vertical view as shown in FIG. 6, the gate capping pattern GP may be disposed between the gate spacer GS and the second interlayer insulating layer 120.

A level of a bottom surface of the gate capping pattern GP may be substantially equal to a level of a top surface of the first interlayer insulating layer 110 in the third direction D3 (i.e., the vertical direction). In other words, in an embodiment, the bottom surface of the gate capping pattern GP may be coplanar with the top surface of the first interlayer insulating layer 110. A level of the top surface GSt of the gate spacer GS may be substantially equal to a level of the top surface of the outer gate electrode PO4 and a level of the top surface of the first interlayer insulating layer 110 in the third direction D3. In other words, in an embodiment, the top surface GSt of the gate spacer GS may be coplanar with the top surface of the outer gate electrode PO4 and the top surface of the first interlayer insulating layer 110. A top surface of the gate insulating layer GI enclosing bottom and side surfaces of the outer gate electrode PO4 may be placed at substantially the same level as the level of the top surface GSt of the gate spacer GS. In other words, in an embodiment, the top surface of the gate insulating layer GI may be coplanar with the top surface GSt of the gate spacer GS. In an embodiment, a height GSH of the gate spacer GS may range from 14 nm to 16 nm. In the present specification, the phrase “substantially the same” may mean that two values are either equal to each other or differ by 2 nm or less.

The gate spacer GS and the active contact AC may be spaced apart from each other in the second direction D2 by a first length DS1. The gate capping pattern GP and the active contact AC may be spaced apart from each other in the second direction D2 by a second length DS2. In an embodiment, the first length DS1 may be substantially equal to the second length DS2. The first and second lengths DS1 and DS2 may range from 6 nm to 9 nm.

A side surface ACs of the active contact AC may be in contact with a silicon oxide layer (i.e., the first and second interlayer insulating layers 110 and 120). The side surface ACs of the active contact AC may be spaced apart from a silicon nitride layer (i.e., the gate capping pattern GP and the gate spacer GS).

In detail, the silicon oxide layer may be provided between the active contact AC and the silicon nitride layer. Since the side surface ACs of the active contact AC is not in contact with the silicon nitride layer, it may be completely spaced apart from the silicon nitride layer. A distance between a side surface of the silicon nitride layer and the side surface ACs of the active contact AC in the second direction D2 may be uniform regardless of a vertical level, as described with reference to the first and second lengths DS1 and DS2.

The active contact AC may include a first portion RE1 and a second portion RE2, and the first portion RE1 may be on the second portion RE2. The first portion RE1 may be a portion of the active contact AC penetrating the first and second interlayer insulating layers 110 and 120. In other words, the first portion RE1 may be a portion of the active contact AC placed at a level higher than a source/drain pattern SD in the third direction D3. The second portion RE2 may be a portion of the active contact AC penetrating an upper portion of the source/drain pattern SD. The first portion RE1 may have a first width W1 in the second direction D2. The second portion RE2 may have a second width W2 in the second direction D2. The second width W2 may be smaller than the first width W1. The first width W1 may be constant regardless of a level of the active contact AC in the third direction D3. A slope of a side surface of the first portion RE1 of the active contact AC may not have an inflection point. Here, the first and second lengths DS1 and DS2 described above may be equal to or greater than half the first width W1. In an embodiment, the first width W1 may range from 9 nm to 12 nm. The second width W2 may range from 6 nm to 9 nm. In some embodiments, the first portion RE1 of the active contact AC may have a tapered shape, unlike the illustrated structure in FIG. 6. Even in this case, the slope of the side surface of the first portion RE1 may not have an inflection point.

In a semiconductor device according to various embodiments described above, a distance from the gate capping pattern and the gate spacer to the active contact may be equal to or larger than half the width of the active contact. In this case, even when there is an error in a process of aligning the active contact to a source/drain pattern, it may be possible to prevent and suppress the gate capping pattern and the gate spacer from being damaged. As a result, a process failure of the semiconductor device may be reduced, and the electric reliability of the semiconductor device may be improved.

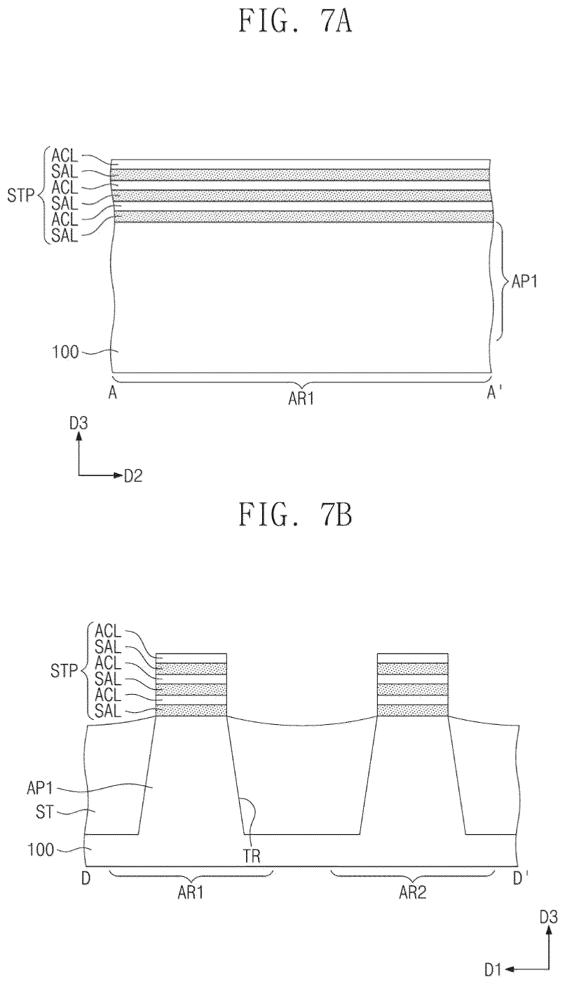

FIGS. 7A, 7B, 8A, 8B, 9A, 9B, 9C, 9D, 10A, 10B, 10C, 10D, 11A, 11B, 11C, 11D, 12A, 12B, 12C, 12D, 13A, 13B, 13C, 13D, 14A, 14B, 14C, 14D, 15A, 15B, 15C, 15D, 16A, 16B, 16C, and 16D are sectional views illustrating a method of fabricating a semiconductor device, according to some embodiments.

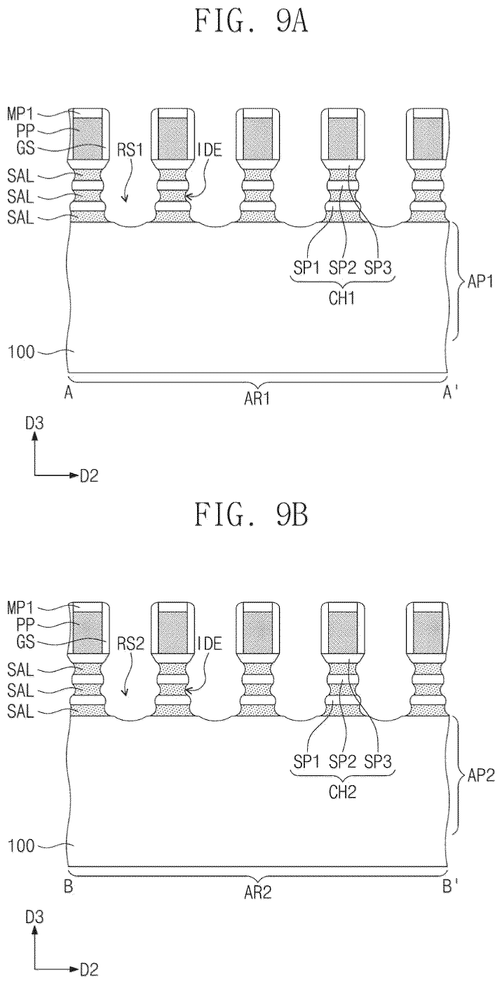

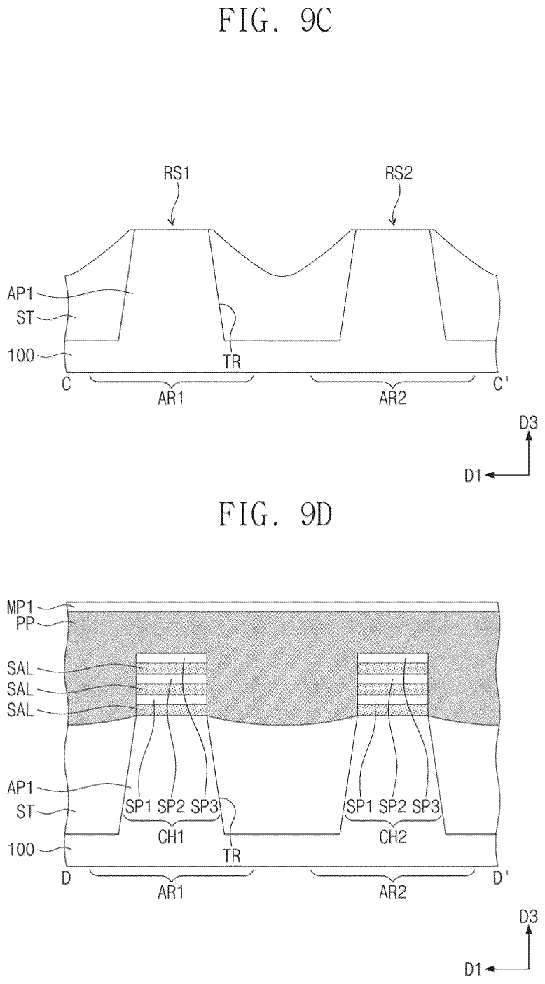

In detail, FIGS. 7A, 8A, 9A, 10A, 11A, 12A, 13A, 14A, 15A, and 16A are sectional views corresponding to the line A-A′ of FIG. 4. FIGS. 9B, 10B, 11B, 12B, 13B, 14B, 15B, and 16B are sectional views corresponding to the line B-B′ of FIG. 4. FIGS. 9C, 10C, 11C, 12C, 13C, 14C, 15C, and 16C are sectional views corresponding to the line C-C′ of FIG. 4. FIGS. 7B, 8B, 9D, 10D, 11D, 12D, 13D, 14D, 15D, and 16D are sectional views corresponding to the line D-D′ of FIG. 4.

Referring to FIGS. 7A and 7B, the substrate 100 including the first and second active regions AR1 and AR2 may be provided. Active and sacrificial layers ACL and SAL may be alternately stacked on the substrate 100. The active and sacrificial layers ACL and SAL may be formed of or include at least one of silicon (Si), germanium (Ge), or silicon-germanium (SiGe). In some embodiments, the active layers ACL may be formed of different materials from materials of the sacrificial layers SAL.

The sacrificial layer SAL may be formed of or include at least one of materials having an etch selectivity with respect to the active layer ACL. For example, in some embodiments, the active layers ACL may be formed of or include silicon (Si), and the sacrificial layers SAL may be formed of or include silicon germanium (SiGe). In some embodiments, a germanium concentration of each of the sacrificial layers SAL may range from 10 at % to 30 at %.

Mask patterns (not shown) may be respectively formed on the first and second active regions AR1 and AR2 of the substrate 100. The mask pattern may be a line- or bar-shaped pattern that is extended in the second direction D2.

A patterning process using the mask patterns as an etch mask may be performed to form the trench TR defining the first and second active patterns AP1 and AP2. The first active pattern AP1 may be formed on the first active region AR1. The second active pattern AP2 may be formed on the second active region AR2.

A stacking pattern STP may be formed on each of the first and second active patterns AP1 and AP2. The stacking pattern STP may include the active layers ACL and the sacrificial layers SAL which are alternately stacked. The stacking pattern STP may be formed along with the first and second active patterns AP1 and AP2, during the patterning process.

The device isolation layer ST may be formed to fill the trench TR. In detail, an insulating layer may be formed on the substrate 100 to cover the first and second active patterns AP1 and AP2 and the stacking patterns STP. The device isolation layer ST may be formed by recessing the insulating layer until the stacking patterns STP are exposed.

The device isolation layer ST may be formed of or include at least one of insulating materials (e.g., silicon oxide). The stacking patterns STP may be placed at a level higher than the device isolation layer ST in the third direction D3 and may be exposed to the outside of the device isolation layer ST. In other words, the stacking patterns STP may protrude above the device isolation layer ST vertically.

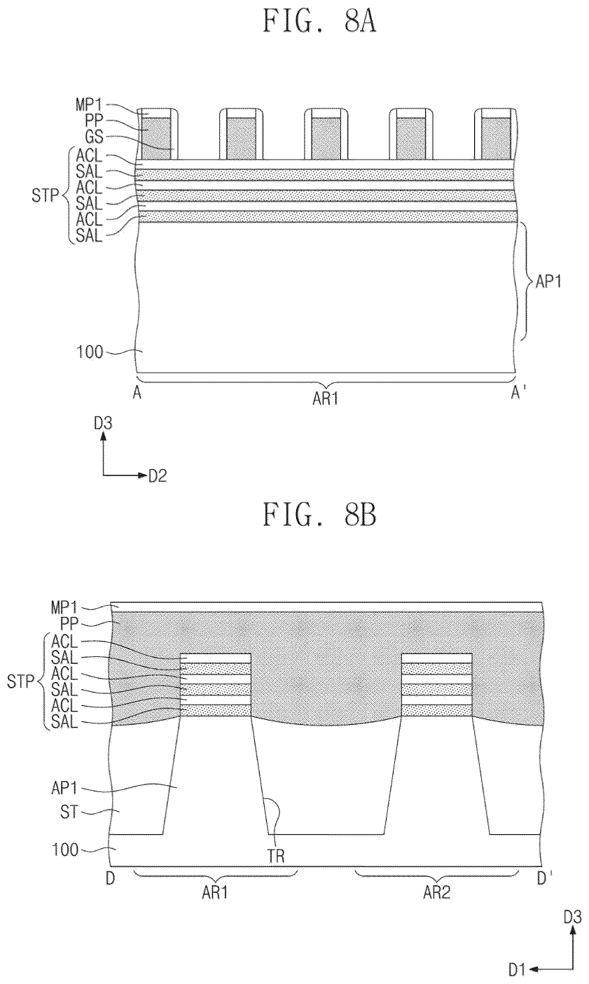

Referring to FIGS. 8A and 8B, sacrificial patterns PP may be formed on the substrate 100 to cross the stacking patterns STP. Each of the sacrificial patterns PP may be a line- or bar-shaped pattern that is extended in the first direction D1. The sacrificial patterns PP may be arranged at a first pitch in the second direction D2.

In detail, the formation of the sacrificial patterns PP may include forming a sacrificial layer on the substrate 100, forming first mask patterns MP1 on the sacrificial layer, and patterning the sacrificial layer using the first mask patterns MP1 as an etch mask. The sacrificial layer may be formed of or include polysilicon.

A pair of the gate spacers GS may be formed on opposite side surfaces of each of the sacrificial patterns PP. For example, a gate spacer GS may be formed on each side surface of the sacrificial patterns PP, as shown in FIG. 8A. The formation of the gate spacers GS may include conformally forming a gate spacer layer on the substrate 100 and anisotropically etching the gate spacer layer.

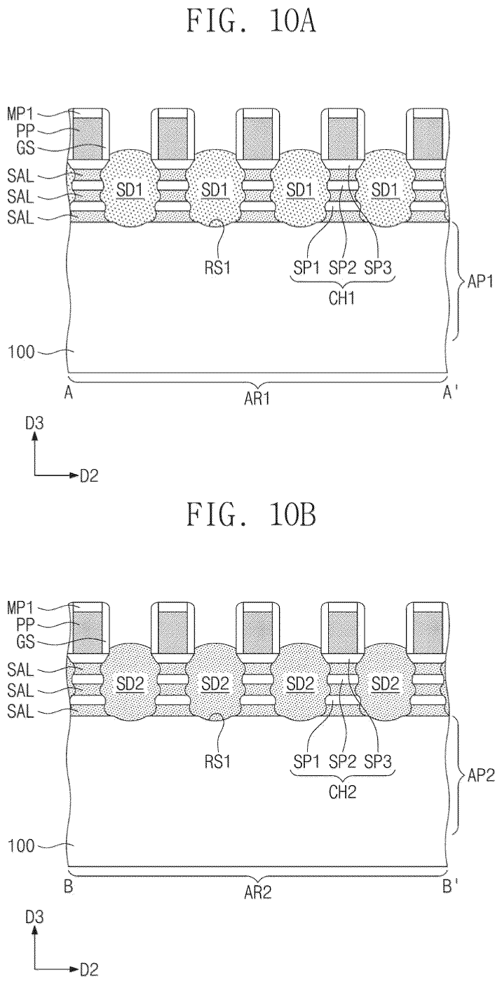

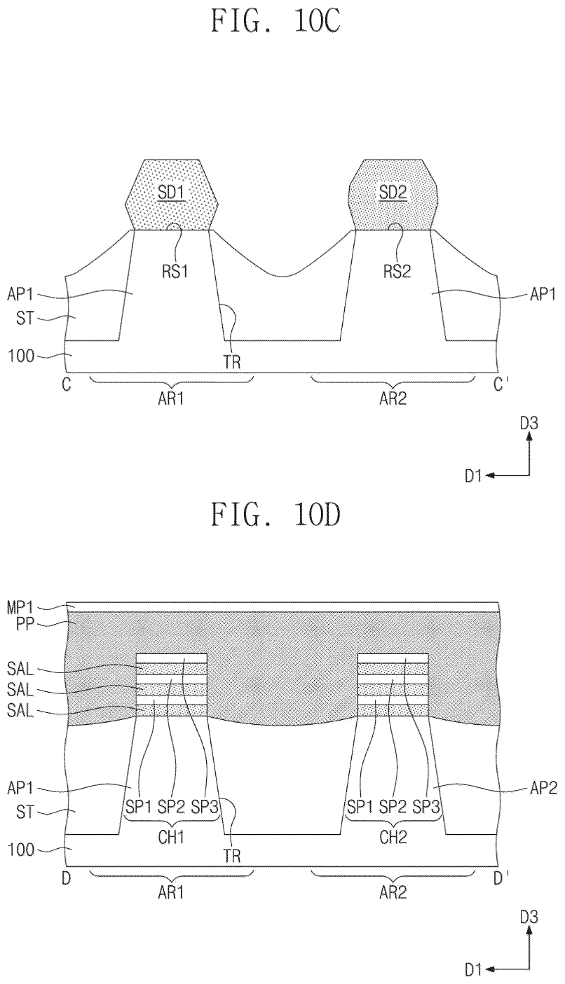

Referring to FIGS. 9A, 9B, and 9C, the first recesses RS1 may be formed in the stacking pattern STP on the first active pattern AP1. The second recesses RS2 may be formed in the stacking pattern STP on the second active pattern AP2. During the formation of the first and second recesses RS1 and RS2, the device isolation layer ST may be recessed at both sides of each of the first and second active patterns AP1 and AP2 (e.g., see FIG. 10C).

In detail, the first recesses RS1 may be formed by etching the stacking pattern STP on the first active pattern AP1 using the first mask patterns MP1 and the gate spacers GS as an etch mask. The first recess RS1 may be formed between a pair of the sacrificial patterns PP. For example, in some embodiments, the first recess RS1 may be formed between adjacent ones of the sacrificial patterns.

In an embodiment, the formation of the first and second recesses RS1 and RS2 may include additionally performing a selective etching process on exposed portions of the sacrificial layers SAL. Each of the sacrificial layers SAL may be indented by the selective etching process to form an indent region IDE. Due to the indent regions IDE, the first and second recesses RS1 and RS2 may have a wave-shaped inner side surface.

The first to third semiconductor patterns SP1, SP2, and SP3, which are sequentially stacked between adjacent ones of the first recesses RS1, may be respectively formed from the active layers ACL. The first to third semiconductor patterns SP1, SP2, and SP3 between the adjacent ones of the first recesses RS1 may constitute the first channel pattern CH1.

The first to third semiconductor patterns SP1, SP2, and SP3, which are sequentially stacked between adjacent ones of the second recesses RS2, may be respectively formed from the active layers ACL. The first to third semiconductor patterns SP1, SP2, and SP3 between the adjacent ones of the second recesses RS2 may constitute the second channel pattern CH2.

Referring to FIGS. 10A, 10B, 10C, and 10D, the first source/drain patterns SD1 may be formed in the first recesses RS1, respectively. In detail, a SEG process, in which an inner surface of the first recess RS1 is used as a seed layer, may be performed to form an epitaxial layer filling the first recess RS1. The epitaxial layer may be grown using the first to third semiconductor patterns SP1, SP2, and SP3 and the substrate 100, which are exposed by the first recess RS1, as the seed layer. In an embodiment, the SEG process may include a chemical vapor deposition (CVD) process or a molecular beam epitaxy (MBE) process.

In an embodiment, the first source/drain pattern SD1 may be formed of or include the same semiconductor element (e.g., Si) as the substrate 100. In some embodiments, during the formation of the first source/drain pattern SD1, the first source/drain pattern SD1 may be doped in-situ with n-type impurities (e.g., phosphorus, arsenic, or antimony). In some embodiments, impurities may be injected into the first source/drain pattern SD1, after the formation of the first source/drain pattern SD1.

The second source/drain patterns SD2 may be formed in the second recesses RS2, respectively. In detail, the second source/drain pattern SD2 may be formed by a SEG process using an inner surface of the second recess RS2 as a seed layer.

In an embodiment, the second source/drain pattern SD2 may be formed of or include a semiconductor material (e.g., SiGe) whose lattice constant is greater than a lattice constant of a semiconductor material of the substrate 100. In some embodiments, during the formation of the second source/drain pattern SD2, the second source/drain pattern SD2 may be doped in-situ with p-type impurities (e.g., boron, gallium, or indium). In some embodiments, impurities may be injected into the second source/drain pattern SD2, after the formation of the second source/drain pattern SD2.

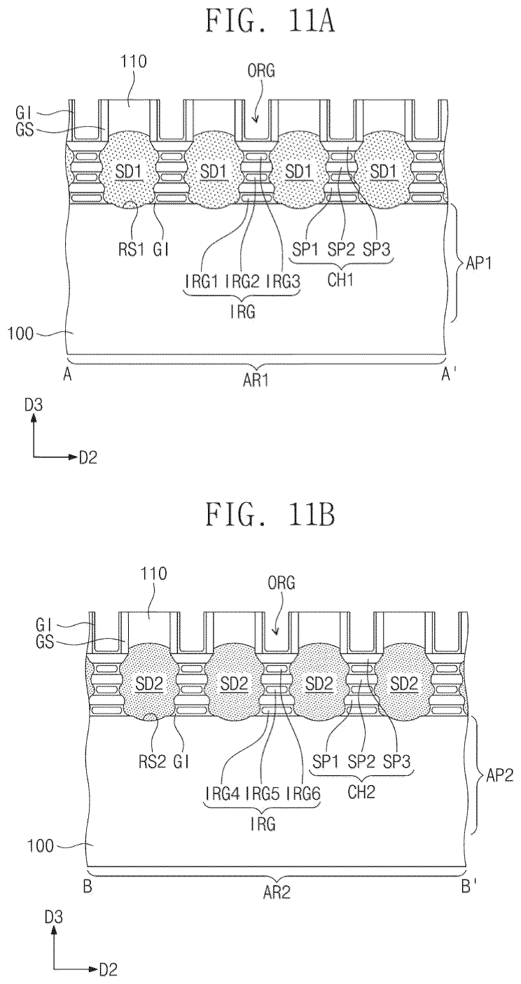

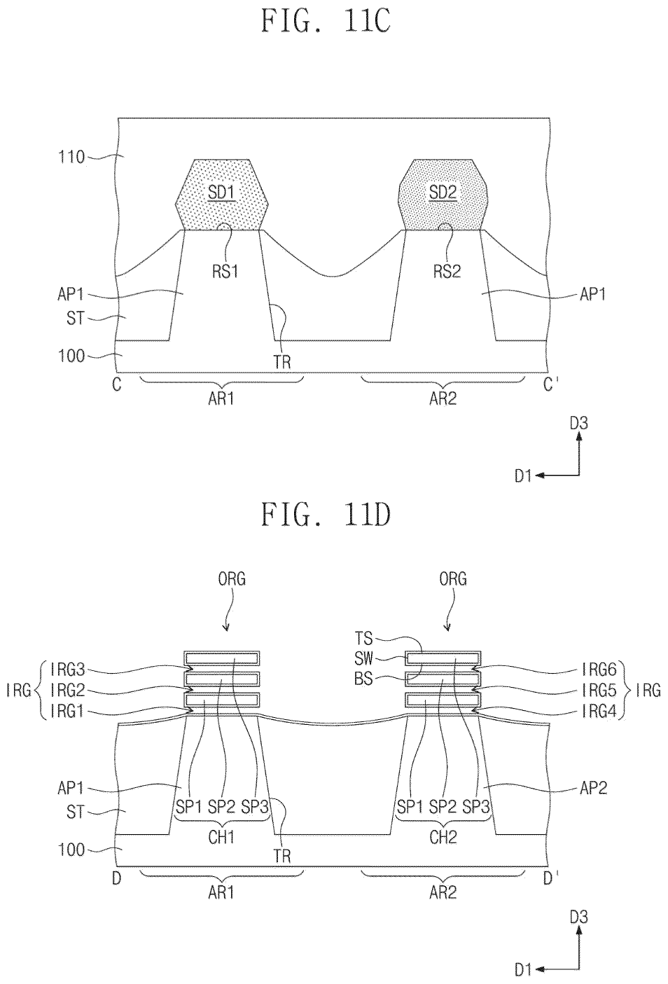

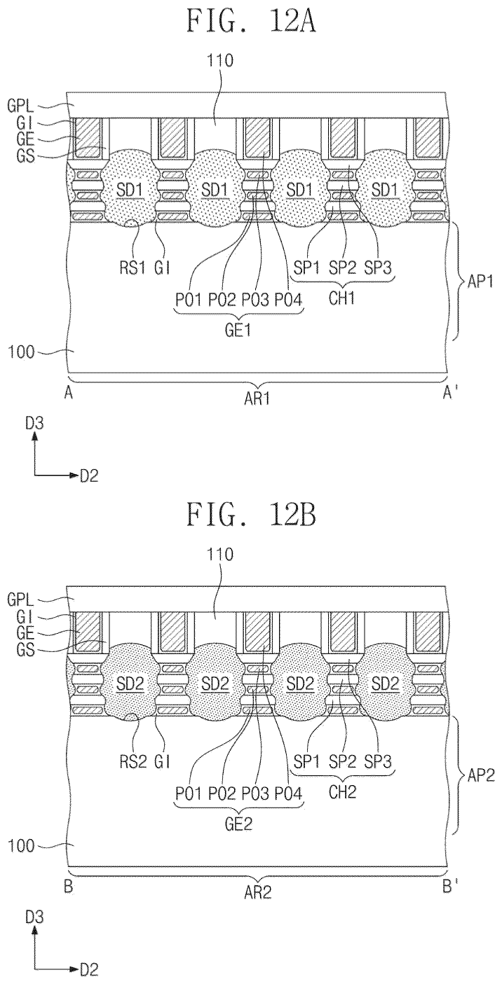

Referring to FIGS. 11A, 11B, and 11C, the first interlayer insulating layer 110 may be formed to cover the first and second source/drain patterns SD1 and SD2, the first mask patterns MP1, and the gate spacers GS. In an embodiment, the first interlayer insulating layer 110 may include a silicon oxide layer.

The first interlayer insulating layer 110 may be planarized to expose the top surfaces of the sacrificial patterns PP. The planarization of the first interlayer insulating layer 110 may be performed using an etch-back or chemical-mechanical polishing (CMP) process. All the first mask patterns MP1 may be removed during the planarization process. As a result, the first interlayer insulating layer 110 may be formed to have a top surface that is coplanar with the top surfaces of the sacrificial patterns PP and the top surfaces of the gate spacers GS.

The exposed sacrificial patterns PP may be selectively removed. As a result of the removal of the sacrificial patterns PP, an outer region ORG exposing the first and second channel patterns CH1 and CH2 may be formed (e.g., see FIG. 11D). The removal of the sacrificial patterns PP may include a wet etching process which is performed using an etching solution capable of selectively etching polysilicon.

The sacrificial layers SAL, which are exposed through the outer region ORG, may be selectively removed to form inner regions IRG (e.g., see FIG. 11D). In detail, a process of selectively etching the sacrificial layers SAL may be performed to leave the first to third semiconductor patterns SP1, SP2, and SP3 and to remove only the sacrificial layers SAL. An etch recipe for the etching process may be chosen to etch a layer (e.g., a silicon germanium layer), which is formed to have a relatively high germanium concentration, at a high etch rate. For example, in some embodiments, the etching process may have a high etch rate to a silicon germanium layer whose germanium concentration is higher than 10 at %.

During the etching process, the sacrificial layers SAL on the first and second active regions AR1 and AR2 may be removed. The etching process may be a wet etching process. An etchant material, which is used in the etching process, may be chosen to quickly remove the sacrificial layer SAL having a relatively high germanium concentration.

Since the sacrificial layers SAL are selectively removed, only the stack of the first to third semiconductor patterns SP1, SP2, and SP3 may be left on each of the first and second active patterns AP1 and AP2. First to third inner regions IRG1, IRG2, and IRG3 on the first active pattern AP1 and fourth to sixth inner regions IRG4, IRG5, and IRG6 on the second active pattern AP2 may be respectively formed by removing the sacrificial layers SAL.

In detail, on the first active pattern AP1, the first inner region IRG1 may be formed between the first active pattern AP1 and the first semiconductor pattern SP1, the second inner region IRG2 may be formed between the first semiconductor pattern SP1 and the second semiconductor pattern SP2, and the third inner region IRG3 may be formed between the second semiconductor pattern SP2 and the third semiconductor pattern SP3.

On the second active pattern AP2, the fourth inner region IRG4 may be formed between the second active pattern AP2 and the first semiconductor pattern SP1, the fifth inner region IRG5 may be formed between the first semiconductor pattern SP1 and the second semiconductor pattern SP2, and the sixth inner region IRG6 may be formed between the second semiconductor pattern SP2 and the third semiconductor pattern SP3.

Next, the gate insulating layer GI may be formed in the first to third inner regions IRG1, IRG2, and IRG3 and the fourth to sixth inner regions IRG4, IRG5, and IRG6. The gate insulating layer GI may be formed in the outer region ORG.

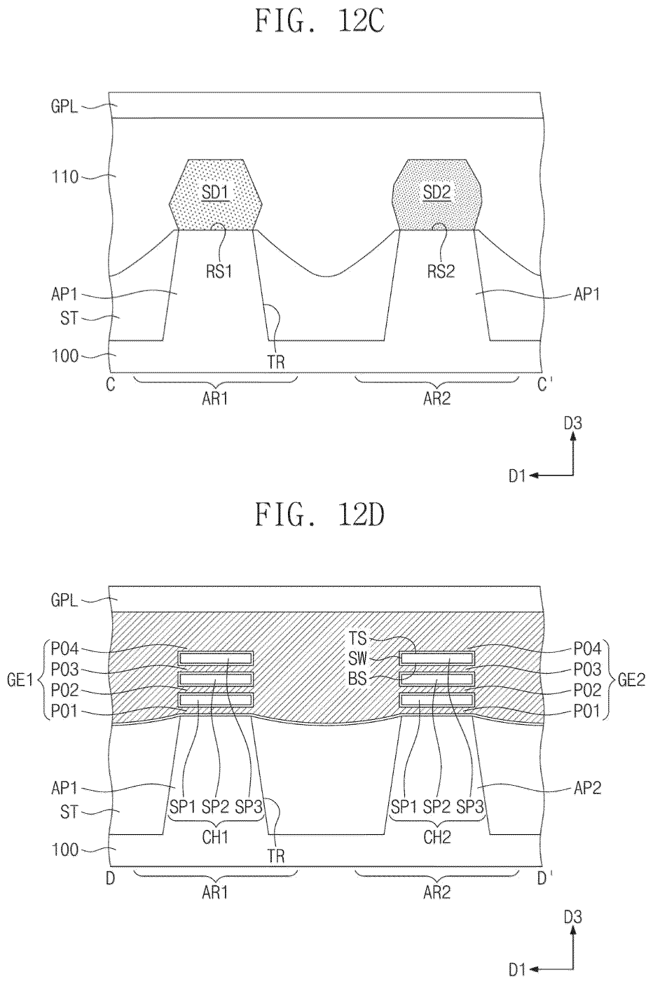

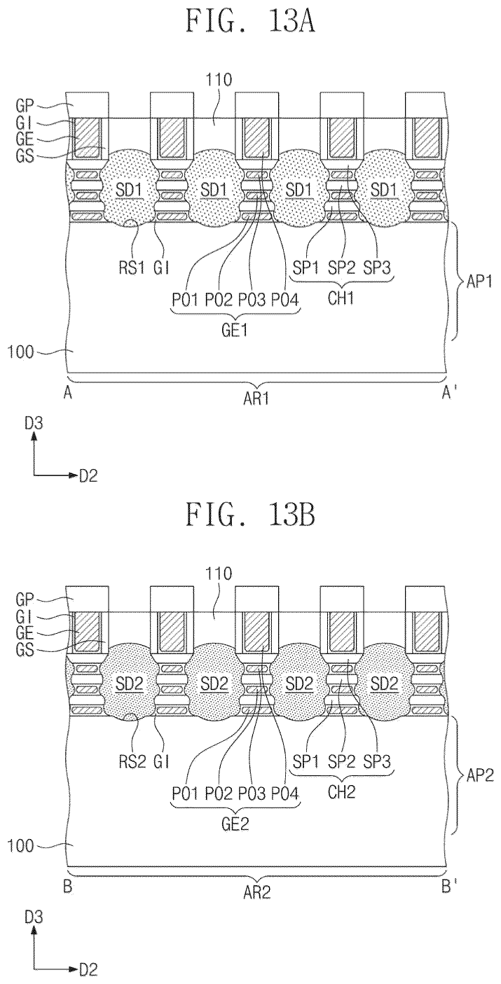

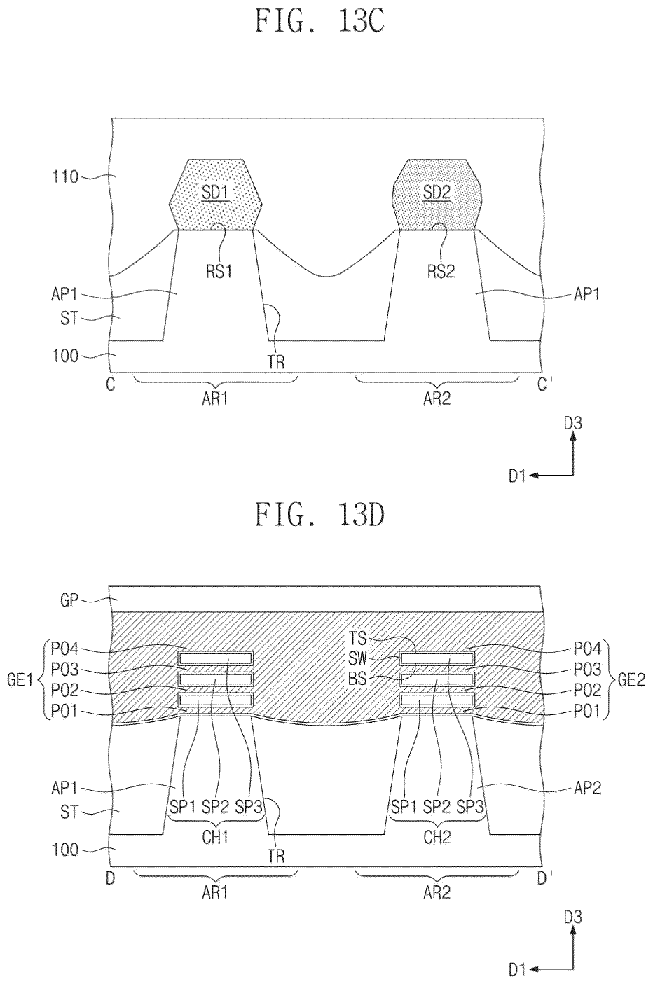

Referring to FIGS. 12A, 12B, 12C, and 12D, the first and second gate electrodes GE1 and GE2 may be formed on the gate insulating layer GI. The first gate electrode GE1 may include the first to third inner gate electrodes PO1, PO2, and PO3, which are formed in the first to third inner regions IRG1, IRG2, and IRG3, respectively, and the outer gate electrode PO4, which is formed in the outer region ORG. The second gate electrode GE2 may include the first to third inner gate electrodes PO1, PO2, and PO3, which are formed in the fourth to sixth inner regions IRG4, IRG5, and IRG6, respectively, and the outer gate electrode PO4, which is formed in the outer region ORG.

Next, a gate capping layer GPL may be formed on the gate spacer GS, the first interlayer insulating layer 110, and the outer gate electrode PO4 of the first and second gate electrodes GE1 and GE2. The gate capping layer GPL may cover the gate spacer GS, the first interlayer insulating layer 110, and the outer gate electrode PO4 of the first and second gate electrodes GE1 and GE2.

Referring to FIGS. 13A, 13B, 13C, and 13D, the gate capping pattern GP may be formed from the gate capping layer GPL. The formation of the gate capping pattern GP may include forming a mask pattern (not shown) on the gate capping layer GPL and patterning the gate capping layer GPL using the mask pattern as an etch mask.

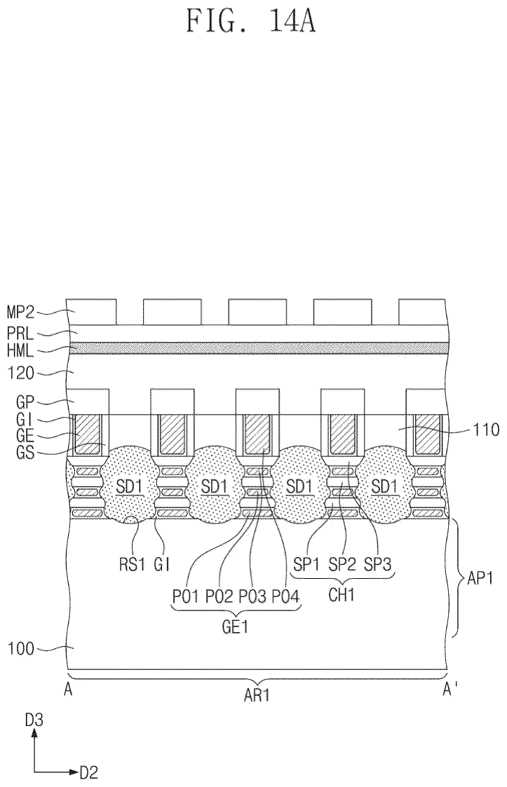

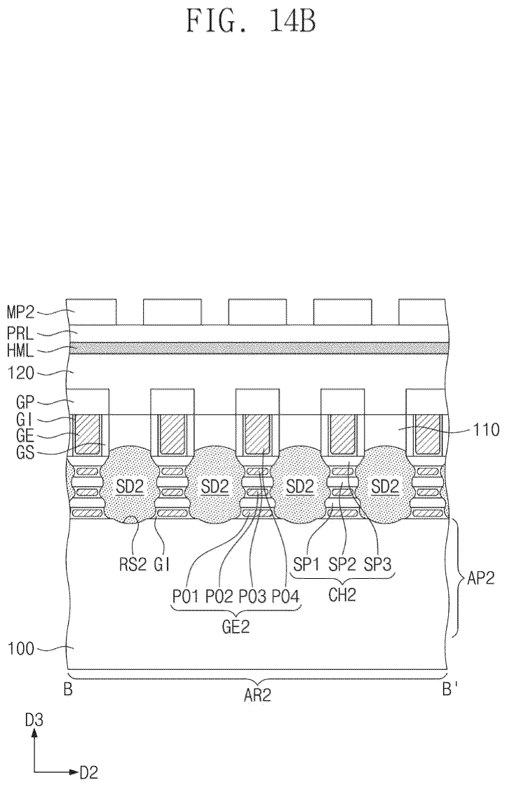

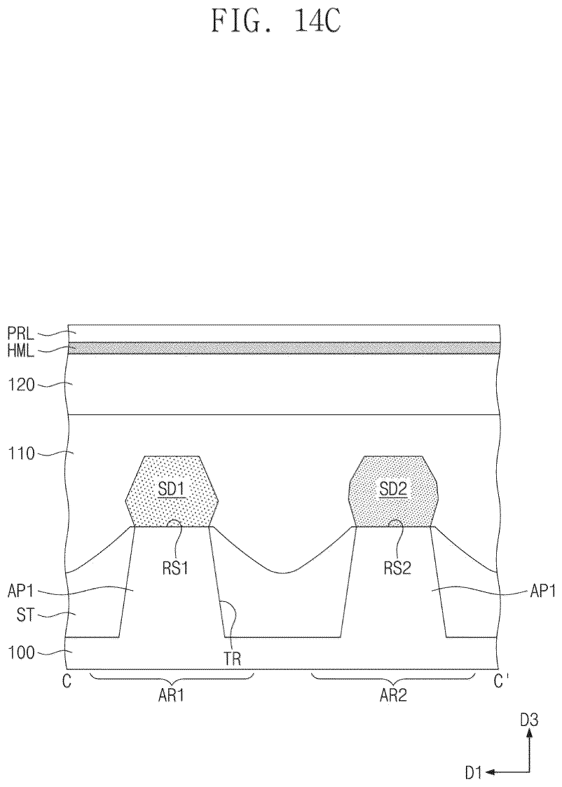

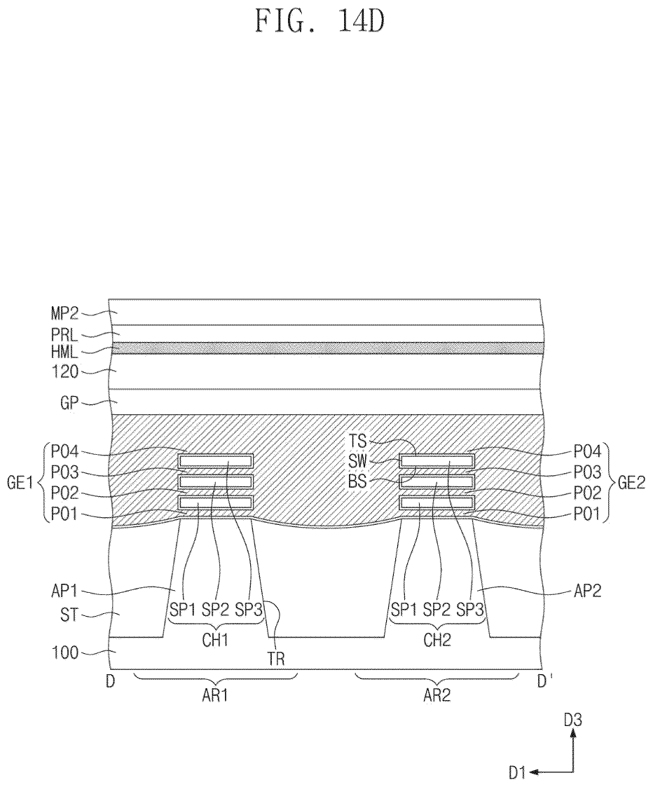

Referring to FIGS. 14A, 14B, 14C, and 14D, the second interlayer insulating layer 120 may be formed on the first interlayer insulating layer 110. The second interlayer insulating layer 120 may cover the gate capping pattern GP. The second interlayer insulating layer 120 may be planarized. The planarization of the second interlayer insulating layer 120 may be performed using an etch-back process or a chemical mechanical polishing (CMP) process.

Next, a hard mask layer HML, a protection insulating layer PRL, and second mask patterns MP2 may be sequentially formed on the second interlayer insulating layer 120. The protection insulating layer PRL may be formed of or include, for example, silicon oxide. The second mask patterns MP2 may define a region, in which the active contact AC described with reference to FIGS. 5A and 5B will be formed.

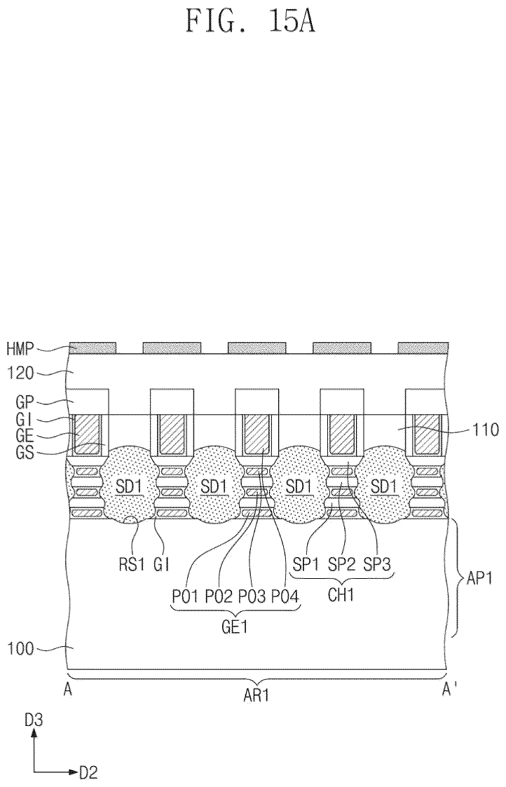

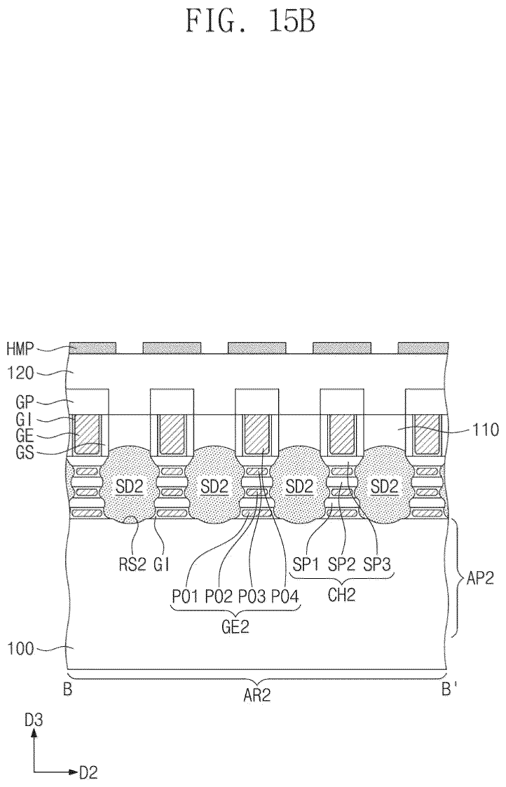

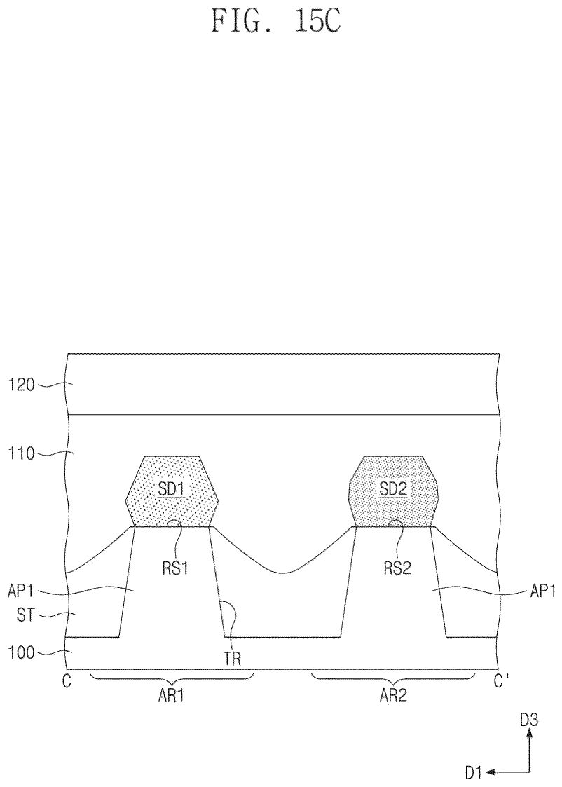

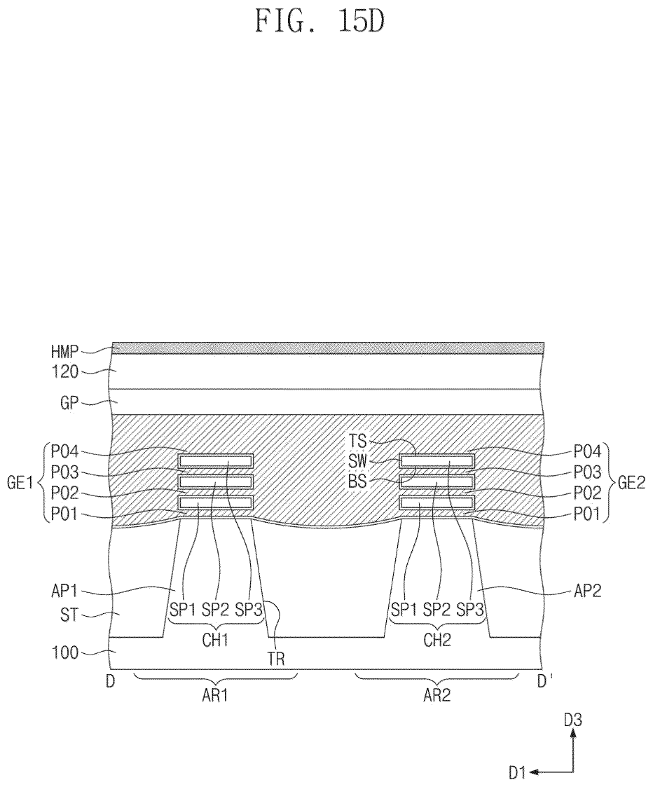

Referring to FIGS. 15A, 15B, 15C, and 15D, the protection insulating layer PRL and the hard mask layer HML may be etched using the second mask patterns MP2 as an etch mask. As a result of the etching process, a hard mask pattern HMP may be formed from the hard mask layer HML. Next, the protection insulating layer PRL, which is left on the hard mask pattern HMP, may be removed.

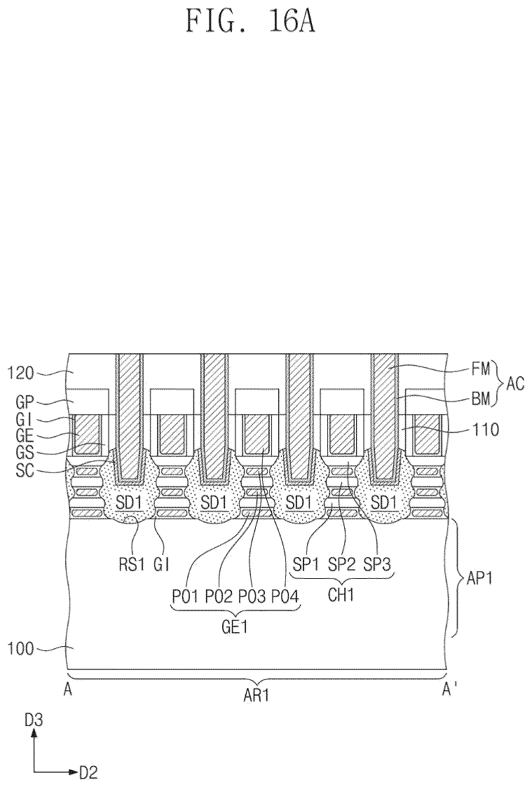

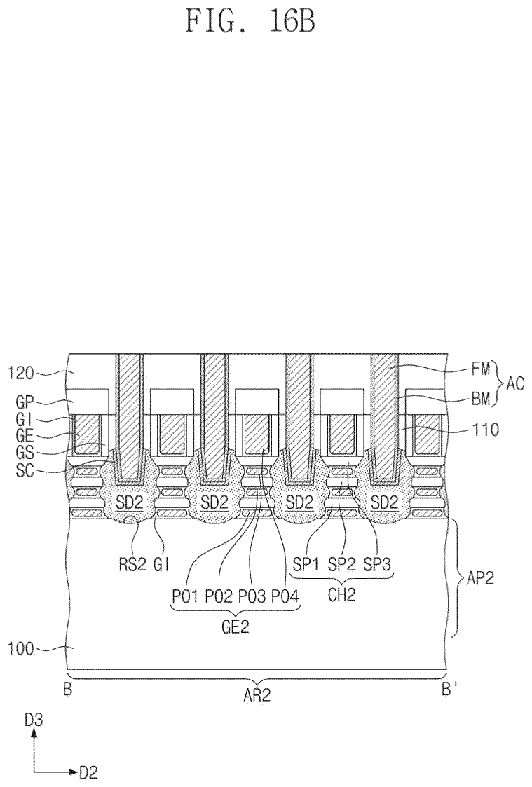

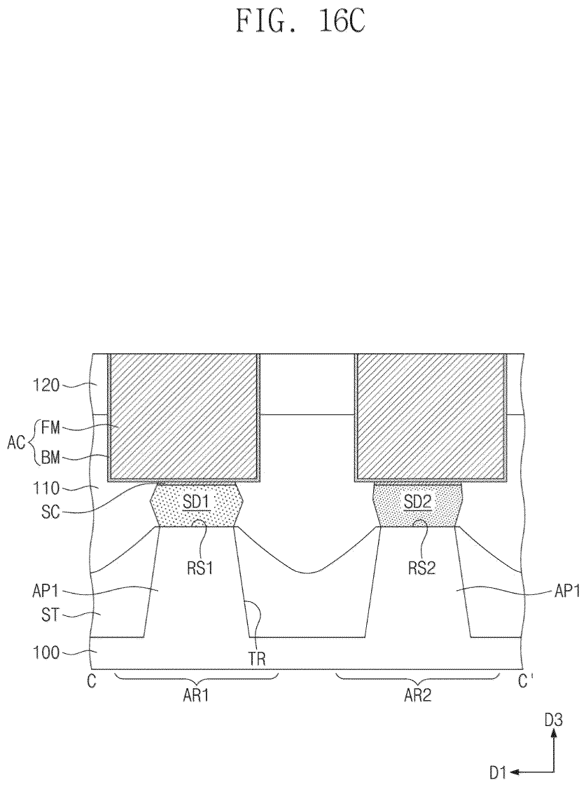

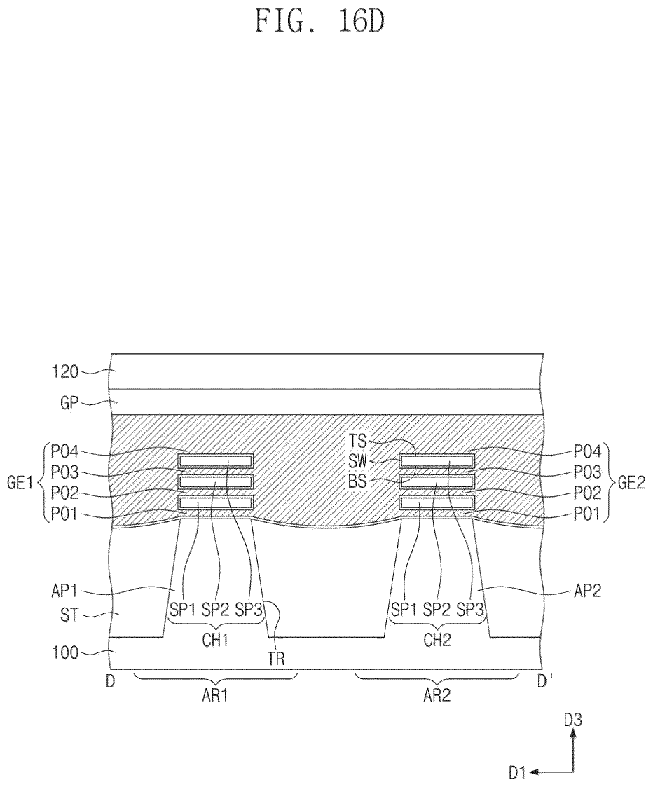

Referring to FIGS. 16A, 16B, 16C, and 16D, the active contacts AC may be formed to penetrate the first and second interlayer insulating layers 110 and 120 and to be electrically connected to the first and second source/drain patterns SD1 and SD2. The formation of the active contact AC may include forming a contact hole in the first and second interlayer insulating layers 110 and 120 using the hard mask pattern HMP as an etch mask, forming the barrier pattern BM in the contact hole, and forming the conductive pattern FM on the barrier pattern BM. Before the formation of the active contact AC, the metal-semiconductor compound layer SC may be formed on the source/drain patterns SD1 and SD2 through a thermal treatment process or the like.

Since both the first and second interlayer insulating layers 110 and 120 include the same material (e.g., silicon oxide), the contact hole may have a uniform etching shape.

As a result, the first width W1 of the first portion RE1 of the active contact AC penetrating the first and second interlayer insulating layers 110 and 120 may be constant regardless of the vertical level of the active contact AC, as shown in FIG. 6. Since the gate capping pattern GP includes a material with an etch selectivity with respect to the first and second interlayer insulating layers 110 and 120, an alignment error in the active contact AC may be reduced or minimized.

Referring back to FIGS. 5A to 5D, the gate contact GC may be formed to penetrate the second interlayer insulating layer 120 and the gate capping pattern GP and to be electrically connected to the gate electrode GE.

The division structures DB may be respectively formed on the first and second borders BD1 and BD2 of the single height cell SHC. The division structure DB may penetrate the second interlayer insulating layer 120 and the gate electrode GE and may extend into the active pattern AP1 or AP2. The division structure DB may be formed of or include at least one of insulating materials (e.g., silicon oxide or silicon nitride).

The third interlayer insulating layer 130 may be formed on the active contacts AC and the gate contacts GC. The first metal layer M1 may be formed in the third interlayer insulating layer 130. The fourth interlayer insulating layer 140 may be formed on the third interlayer insulating layer 130. The second metal layer M2 may be formed in the fourth interlayer insulating layer 140.

In a semiconductor device according to various embodiments, a distance between a gate capping pattern and an active contact may be equal to or greater than half a width of the active contact. In this case, even when there is an error in a process of aligning the active contact to a source/drain pattern, it may be possible to prevent and suppress the gate capping pattern and a gate spacer from being damaged. As a result, a process failure of the semiconductor device may be reduced, and the electric reliability of the semiconductor device may be improved.

While various example embodiments have been particularly shown and described with respect to the drawings, it will be understood by one of ordinary skill in the art that variations in form and detail may be made therein without departing from the spirit and scope of the attached claims.

What is claimed is:

1. A semiconductor device comprising:
a substrate including an active pattern;
a channel pattern on the active pattern, the channel pattern comprising a plurality of semiconductor patterns, which are vertically stacked and are spaced apart from each other in a vertical direction;
a source/drain pattern connected to the channel pattern;
an inner gate electrode interposed between adjacent ones of the plurality of semiconductor patterns;
an outer gate electrode on an uppermost one of the plurality of semiconductor patterns;
a gate spacer on a side surface of the outer gate electrode; and
a gate capping pattern on a top surface of the outer gate electrode,
wherein the gate capping pattern is in contact with a top surface of the gate spacer.

2. The semiconductor device of claim 1, further comprising a first interlayer insulating layer covering the source/drain pattern,
wherein the gate capping pattern is at a vertical level higher than a vertical level of the first interlayer insulating layer.

3. The semiconductor device of claim 2, wherein a vertical level of a bottom surface of the gate capping pattern is substantially equal to a vertical level of a top surface of the first interlayer insulating layer.

4. The semiconductor device of claim 2, further comprising a second interlayer insulating layer on the first interlayer insulating layer,
wherein the second interlayer insulating layer covers side surfaces and a top surface of the gate capping pattern.

5. The semiconductor device of claim 4, wherein the gate capping pattern is disposed between the gate spacer and the second interlayer insulating layer, when viewed in a vertical section.

6. The semiconductor device of claim 4, wherein the gate capping pattern comprises at least one of silicon oxynitride, silicon nitride, or silicon carbon nitride, and
each of the first interlayer insulating layer and the second interlayer insulating layer comprise silicon oxide.

7. The semiconductor device of claim 1, wherein a height of the gate spacer is from 14 nm to 16 nm.

8. The semiconductor device of claim 1, further comprising a gate insulating layer enclosing a bottom surface and side surfaces of the outer gate electrode,
wherein a vertical level of a top surface of the gate insulating layer is substantially equal to a vertical level of the top surface of the gate spacer.

9. The semiconductor device of claim 1, wherein a vertical level of the top surface of the outer gate electrode is substantially equal to a vertical level of the top surface of the gate spacer.

10. A semiconductor device comprising:
a substrate including an active pattern;
a channel pattern on the active pattern, the channel pattern comprising a plurality of semiconductor patterns, which are vertically stacked and are spaced apart from each other in a vertical direction;
a source/drain pattern connected to the channel pattern;
an inner gate electrode interposed between adjacent ones of the plurality of semiconductor patterns;
an outer gate electrode on an uppermost one of the plurality of semiconductor patterns;
a silicon nitride layer on side surfaces and a top surface of the outer gate electrode;
a silicon oxide layer covering the source/drain pattern; and
an active contact that penetrates the silicon oxide layer and is connected to the source/drain pattern,
wherein a side surface of the active contact is in contact with the silicon oxide layer and is spaced apart from the silicon nitride layer.

11. The semiconductor device of claim 10, wherein the silicon oxide layer is between the active contact and the silicon nitride layer.

12. The semiconductor device of claim 10, wherein a distance between a side surface of the silicon nitride layer and the side surface of the active contact in a first direction is constant regardless of a vertical level.

13. The semiconductor device of claim 10, wherein a portion of the active contact located at a vertical level higher than a vertical level of the source/drain pattern has a constant width in a first direction, regardless of a vertical level of the portion.

14. A semiconductor device comprising:
a substrate including an active pattern;
a channel pattern on the active pattern, the channel pattern comprising a plurality of semiconductor patterns, which are vertically stacked and are spaced apart from each other in a vertical direction;
a source/drain pattern connected to the channel pattern;
an inner gate electrode interposed between adjacent ones of the plurality of semiconductor patterns;
an outer gate electrode on an uppermost one of the plurality of semiconductor patterns;
a gate spacer on a side surface of the outer gate electrode;
a gate capping pattern on a top surface of the outer gate electrode;
a first interlayer insulating layer covering the source/drain pattern;
a second interlayer insulating layer on the first interlayer insulating layer; and
an active contact that penetrates the first interlayer insulating layer, the second interlayer insulating layer, and an upper portion of the source/drain pattern,
wherein the gate capping pattern is spaced apart from the active contact in a first direction,
wherein the active contact comprises:
a first portion that penetrates the first interlayer insulating layer and the second interlayer insulating layer; and
a second portion that penetrates the upper portion of the source/drain pattern,
wherein the first portion has a first width in the first direction, and
a distance between the gate capping pattern and the active contact in the first direction is equal to or greater than half the first width.

15. The semiconductor device of claim 14, wherein the gate capping pattern is in the second interlayer insulating layer.

16. The semiconductor device of claim 14, wherein the first width is constant regardless of a vertical level of the active contact.

17. The semiconductor device of claim 14, wherein the second portion has a second width in the first direction,
the first width is from 9 nm to 12 nm, and
the second width is from 6 nm to 9 nm.

18. The semiconductor device of claim 14, wherein a distance between the gate spacer and the active contact in the first direction is from 6 nm to 9 nm.

19. The semiconductor device of claim 14, wherein a vertical level of the top surface of the outer gate electrode is substantially equal to a vertical level of a top surface of the gate spacer.

20. The semiconductor device of claim 14, wherein the gate spacer is spaced part from the active contact in the first direction, and
a distance between the gate spacer and the active contact in the first direction is equal to or greater than half the first width.
